(19) United States
(12) Patent Application Publication
(10) Pub. No.: US 2008/0182179 A1
(43) Pub. Date: Jul. 31, 2008

(54) GRAY TONE MASK AND METHOD FOR MANUFACTURING THE SAME

(75) Inventor: Robert Chin Fu TSAI, Hsin Chu City (TW)

Correspondence Address: LOWE HAUPTMAN HAM & BERNER, LLP, 1700 DIAGONAL ROAD, SUITE 300, ALEXANDRIA, VA, 22314, US

(73) Assignee: ALLIED INTEGRATED PATTERNING CORP., Hsinchu (TW)

(21) Appl. No.: 11/627,277

(22) Filed: Jan. 25, 2007

(51) Int. Cl. G03F 1/00; G03F 7/26

(52) U.S. Cl. 430/5; 430/323

(57) ABSTRACT

A gray tone mask includes a transparent substrate and a light blocking layer. The light blocking layer is disposed on the transparent substrate and has a transparent region with a minimum thickness, an opaque region with a maximum thickness and a gray tone region with an intermediate thickness, wherein the intermediate thickness is between the minimum thickness and the maximum thickness, and the optical transmissivity of the gray tone region is approximately between 5% and 95%.

### BACKGROUND OF THE INVENTION

1. Field of the Invention

The present invention generally relates to a gray tone mask, and more particularly to a gray tone mask of simpler structure which can be easily manufactured.

2. Description of the Related Art

For manufacturing semiconductors or thin film transistor liquid crystal displays, photolithography and etching processes are very important. The conventional photolithography process mainly includes the following steps: coating a photo-resist, exposing the photo-resist, and developing the photo-resist. Referring to FIG. 1, a photo-resist 12 is formed on a work-piece 14. Then, parallel light 16 from a light source irradiates the photo-resist 12 through a photo-mask 10. Since the photo-mask 10 has a predetermined pattern 18 for reflecting part of incident light, the light 16 through the photo-mask 10 selectively exposes the photo-resist 12, whereby the pattern 18 can be transferred to the photo-resist 12 on the work-piece 14. Then, the exposed photo-resist 12 can be developed so as to be patterned, whereby the patterned photo-resist 12 has a pattern 18′ which is the same as the pattern 18 of the photo-mask 10. This pattern transferring manner is called as positive type, shown in FIG. 2. On the contrary, the exposed photo-resist 12 is developed so as to be patterned, whereby the patterned photo-resist 12 has a pattern 20 which is complementary to the pattern 18 of the photo-mask 10. This pattern transferring manner is called as negative type, shown in FIG. 3. Then, the work-piece 14 is etched so as to be patterned, whereby the work-piece 14 has a pattern which is the same as the pattern of the patterned photo-resist 12. Finally, the photo-resist 12 is removed so as to finish the photolithography and etching processes.

Generally, a method for manufacturing a semiconductor or a thin film transistor liquid crystal display includes a plurality of photolithography and etching processes for forming multiple thin films of various specific patterns. During conventional photolithography processes, for example, there are a plurality of exposure steps to be carried out by means of a plurality of binary masks, whereby different amount of light transmission is distributed on the region to be etched. However, the more number of exposure steps are, the more manufacture time and cost will require. Currently, a gray tone mask has been developed and can replace the binary mask so as to decrease the number of exposure steps and thus simplify photolithography processes.

U.S. Pat. No. 6,876,428, entitled “Method of Manufacturing A Liquid Crystal Display Panel Using A Gray Tone Mask” discloses a method of forming a pattern in a display device, comprising the following steps of: providing a thin film; depositing a photo-sensitive layer on the thin film; exposing the photo-sensitive layer with light by using a mask having a transparent portion and a partial transparent portion so as to pattern the photo-sensitive layer, the partial transparent portion including at least two portions having the different transparent ratios for introducing light in different quantities to the photo-sensitive layer in accordance with the irradiating direction of the light; and etching the thin film by using the patterned photo-sensitive layer. However, the gray tone mask disclosed in U.S. Pat. No. 6,876,428 is a slit mask of which partial transparent portion includes a plurality of slits which are spaced out a predetermined gap apart for introducing different quantities of light transmission along the irradiating direction of the light.

Furthermore, U.S. Pat. No. 5,213,916, entitled “Method of Making A Gray Level Mask” discloses a gray level mask suitable for a photolithography process. The gray level mask is constructed of a transparent glass substrate which supports plural levels of materials having different optical transmissivities. In the case of a mask employing only two of these levels, the first level may be constructed of a glass made partially transmissive by substitution of silver ions in place of metal ions of alkali metal silicates employed in the construction of the glass. The second layer may be made opaque by construction of the layer of a metal such as chromium. The mask is fabricated with the aid of a photoresist structure which is etched in specific regions by photolithographic masking to enable selective etching of exposed regions of the level of materials of differing optical transmissivities. However, the gray level mask of U.S. Pat. No. 5,213,916 includes at least two levels of materials disposed on the transparent glass substrate, wherein the first level is constructed of a glass made partially transmissive, and the second layer is made opaque.

Furthermore, referring to FIG. 4, Japan Patent Publication Number 2003-156766, entitled “Reflection Type Liquid Crystal Display Unit And Its Manufacturing Method”, discloses a conventional reflective liquid crystal display device 50 including a thin film transistor substrate 60, a color filter substrate 80 and a liquid crystal layer 52 located between the thin film transistor substrate 60 and the color filter substrate 80. The thin film transistor substrate 60 includes a plurality of pixel regions, wherein each pixel region includes a thin film transistor 62, an insulating layer 64 and a reflective electrode 66 formed on a transparent substrate 68 in sequence. The insulating layer 64 has a structure of contact holes 72 and concave-convex surfaces 74 by using a photolithography process and a one-sheet mask (not shown). The reflective electrode 66 is formed on the concave-convex surface 74 of the insulating layer 64 and electrically connected to the thin film transistor 62. The reflective electrode 66 can reflect the external light unsymmetrically. The insulating layer 64 is made of organic material or inorganic material, and protects the thin film transistor 62. The color filter substrate 80 includes a color filter layer 82 and an opposing transparent electrode 84 formed on another transparent substrate 86 in sequence.

The above-mentioned Japanese patent discloses that the one-sheet mask includes contact patterns and concave-convex patterns corresponding to the contact holes 72 and the concave-convex surfaces 74 of the insulating layer 64, and the insulating layer 64 is simultaneously formed with the contact holes 72 and the concave-convex surfaces 74 in sequential photolithography process by controlling the amount of light transmission of the contact pattern being more than that of concave-convex pattern. However, the above-mentioned Japanese patent fails to disclose the components of the one-sheet mask, and the material and property of the component.

Accordingly, there exists a need for a gray tone mask which is simple in structure, can be easily manufactured.

### SUMMARY OF THE INVENTION

It is an object of the present invention to provide a gray tone mask which is simple in structure and can be easily manufactured.

It is another object of the present invention to provide a gray tone mask including a gray tone region, wherein the optical transmissivity of the gray tone region is approximately between 5% and 95%.

In order to achieve the foregoing objects, the present invention provides a gray tone mask including a transparent substrate and a light blocking layer. The light blocking layer is disposed on the transparent substrate and has a transparent region with a minimum thickness, an opaque region with a maximum thickness and a gray tone region with an intermediate thickness, wherein the intermediate thickness is between the minimum thickness and the maximum thickness, and the optical transmissivity of the gray tone region is approximately between 5% and 95%.

The gray tone mask of the present invention can replace the conventional binary mask so as to decrease the number of exposure steps and thus simplify photolithography processes. Furthermore, the gray tone mask of the present invention is different from the conventional slit mask, and does not require at least two light blocking layers disposed on the transparent substrate. Compared with the prior art, the gray tone mask of the present invention is simply structured, easily manufactured, and different from the structure of conventional gray tone mask.

The foregoing, as well as additional objects, features and advantages of the invention will be more apparent from the following detailed description, which proceeds with reference to the accompanying drawings.

### BRIEF DESCRIPTION OF THE DRAWINGS

FIG. 1 is a cross-sectional schematic view of an exposure step of a photolithography process in the prior art.

FIG. 2 is a cross-sectional schematic view of a developing step of a photolithography process in the prior art, showing that the pattern transferring manner is a positive type.

FIG. 3 is a cross-sectional schematic view of a developing step of a photolithography process in the prior art, showing that the pattern transferring manner is a negative type.

FIG. 4 is a cross-sectional schematic view of a reflective type liquid crystal display device in the prior art.

FIG. 5 is a cross-sectional schematic view of a gray tone mask according to an embodiment of the present invention.

FIG. 6 is a cross-sectional schematic view of a gray tone mask according to an alternative embodiment of the present invention.

FIGS. 7 to 9 are cross-sectional schematic views of methods for manufacturing the gray tone mask in the embodiment.

FIGS. 10 to 15 are cross-sectional schematic views of a method for manufacturing the liquid crystal display device by using the gray tone mask in the embodiment.

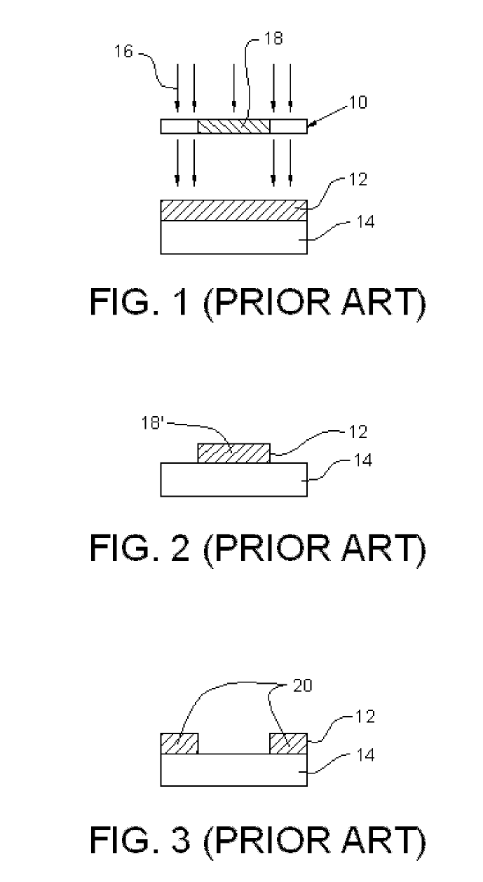

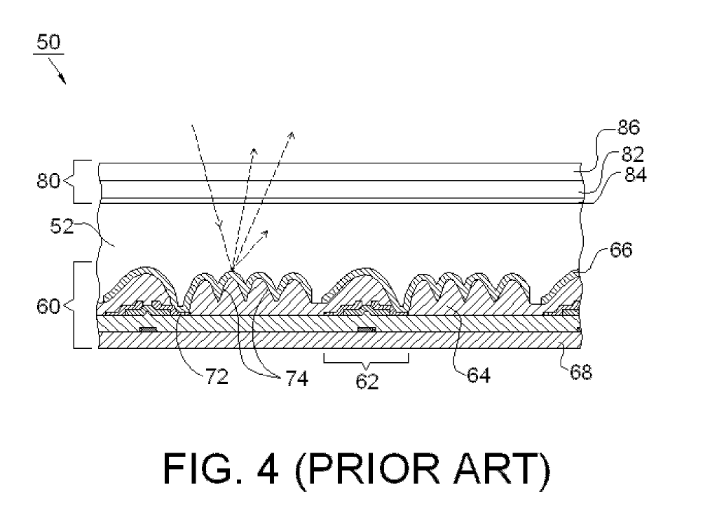

### DETAILED DESCRIPTION OF THE PREFERRED EMBODIMENT

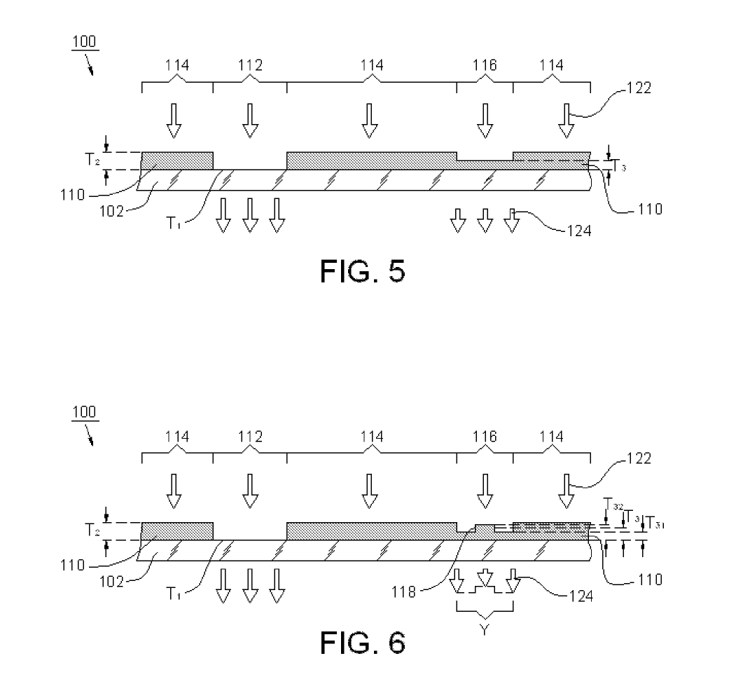

Referring to FIG. 5, it depicts a gray tone mask 100 according to an embodiment of the present invention. The gray tone mask 100 includes a transparent substrate 102 (e.g. glass substrate) and a light blocking layer 110. The light blocking layer 110 is disposed on the transparent substrate and has a transparent region 112 with a minimum thickness T1, an opaque region 114 with a maximum thickness T2 and a gray tone region 116 with an intermediate thickness T3, wherein the intermediate thickness T3 is between the minimum thickness T1 and the maximum thickness T2.

According to the definition of optical transmissivity, the optical transmissivity is the percentage (ratio) of the strength of transmissive light to that of incident light. The amount of light transmission depends on the thickness of the light blocking layer 110, and thus it is very important to control the thickness of the light blocking layer 110, i.e. the optical transmissivity. In this embodiment, the optical transmissivity of the transparent region 112 is 100% by controlling the minimum thickness T1, the optical transmissivity of the opaque region 114 is 0% by controlling the maximum thickness T2, and the optical transmissivity of the gray tone region 116 is approximately between 5% and 95% by controlling the intermediate thickness T3, preferably.

More detailed, the transparent region 112 is fully clear, i.e. the optical transmissivity of the transparent region 112 is 100% when the value of the minimum thickness T1 is zero. The opaque region 114 is fully opaque, i.e. the optical transmissivity of the opaque region 114 is 0% when the value of the maximum thickness T2 is more than a predetermined value. For example, if the light blocking layer 110 is made of chromium (Cr), the optical transmissivity of the opaque region 114 is 0% when the value of the maximum thickness T2 is more than 1000 angstroms (A). The gray tone region 116 is partially transmissive, i.e. the optical transmissivity of the gray tone region 116 is approximately between 5% and 95% when the intermediate thickness T3 is between the minimum thickness T1 and the maximum thickness T2. For example, if the light blocking layer 110 is made of chromium (Cr), the optical transmissivity of the gray tone region 116 is 5% and 95% approximately when the intermediate thickness T3 is 490 A and 190 A respectively. It is noted that the gray-tone phenomenon of the gray tone region 116 beyond the optical transmissivities of 5%-95% is not distinguishable. Thus, it is valueless for the optical transmissivity of the gray tone region 116 to utilize 0%-5% and 95%-100%.

Referring to FIG. 6, in an alternative embodiment, the amount Y of light transmission of the gray tone region 116 depends on the thickness T3 of the light blocking layer 110. If the light blocking layer 110 includes a concave-convex pattern 118 on the gray tone region 116, i.e. the intermediate thickness T3 includes a plurality of levels of thickness, e.g. a first thickness T31 and a second thickness T32 (wherein T32 is bigger than T31), the distribution of the amount Y of light transmission of the gray tone region 116 is corresponding to the first and second thicknesses T31, T32 of the concave-convex pattern 118. Thus, the gray tone region 116 has a plurality of levels of the optical transmissivity, e.g. a first optical transmissivity and a second optical transmissivity, wherein the first and second optical transmissivities are corresponding to the first and second thicknesses T31, T32 respectively.

Furthermore, a metallic material has better adhesion to the transparent substrate 102 (e.g. glass substrate), and thus the light blocking layer 110 has better adhesion to the transparent substrate 102 when the light blocking layer 110 is made of the metallic material. Preferably, the metallic material is selected from one of the group consisting of chromium, aluminum, tungsten, molybdenum, nickel, tantalum and their compounds.

A nonmetallic material is easily formed to a specific profile on the transparent substrate 102 (e.g. glass substrate), and thus the light blocking layer 110 is easily formed to a specific profile on the transparent substrate 102 when the light blocking layer 110 is made of the nonmetallic material. Preferably, the nonmetallic material is silicon or its compound.

The gray tone mask of the present invention can replace the binary mask so as to decrease the number of exposure steps and thus simplify photolithography processes. Furthermore, the gray tone mask of the present invention requires only one light blocking layer disposed on the transparent substrate, and doses not require additional (gray tone) layers.

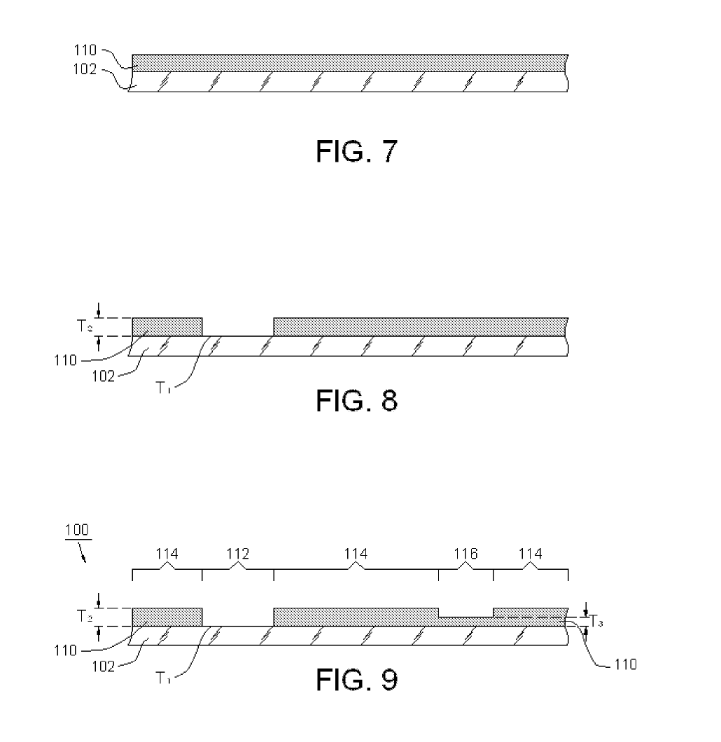

The method for manufacturing the gray tone mask in this embodiment includes the following steps. Referring to FIG. 7, a transparent substrate 102 is provided, and then a light blocking layer 110 is formed on the transparent substrate 102, wherein the light blocking layer 110 has a maximum thickness T2. Referring to FIG. 8, a part of the light blocking layer 110 is patterned and formed with a minimum thickness T1 by using first photolithography/etching processes. Referring to FIG. 9, another part of the light blocking layer 110 is patterned and formed with an intermediate thickness T3 by using second photolithography/etching processes, wherein the minimum thickness T1, the maximum thickness T2 and the intermediate thickness T3 define a transparent region 112, an opaque region 114 and a gray tone region 116 respectively, the intermediate thickness T3 is between the minimum thickness T1 and the maximum thickness T2, and the optical transmissivity of the gray tone region 116 is approximately between 5% and 95%.

Another method for manufacturing the gray tone mask in this embodiment includes the following steps. A transparent substrate 102 is provided, and then a light blocking layer 110 is formed on the transparent substrate 102, shown in FIG. 7, wherein the light blocking layer 110 has a maximum thickness T2.

A part of the light blocking layer 110 is patterned and formed with a minimum thickness T1 and an intermediate thickness T3 simultaneously by using photolithography/etching processes and a laser assisted process, shown in FIG. 9, wherein the minimum thickness T1, the maximum thickness T2 and the intermediate thickness T3 define a transparent region 112, an opaque region 114 and a gray tone region 116 respectively, the intermediate thickness T3 is between the minimum thickness T1 and the maximum thickness T2, and the optical transmissivity of the gray tone region 116 is approximately between 5% and 95%. More detailed, during etching process the etching rate of the light blocking layer 110 located on the transparent region 112 is accelerated by the laser assisted process, whereby the light blocking layer 110 is patterned and formed with the minimum thickness T1 and the intermediate thickness T3 simultaneously.

Compared with the prior art, the gray tone mask of the present invention is simply structured, easily manufactured, and different from the structure of conventional gray tone mask.

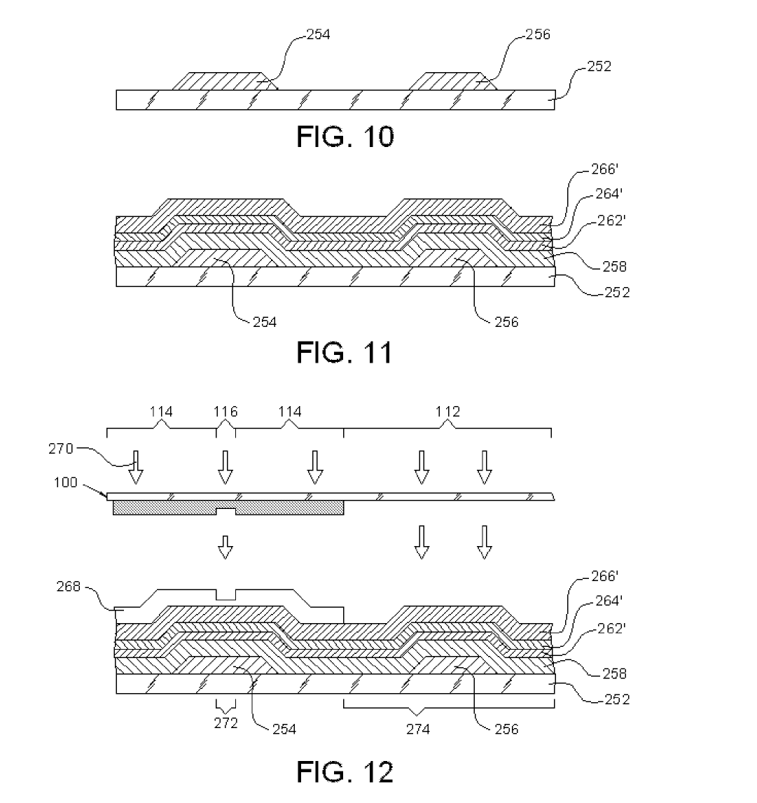

In addition, the present invention provides a method for manufacturing the liquid crystal display device by using the gray tone mask in this embodiment. The method includes the following steps. Referring to FIG. 10, a first metallic layer is formed on a transparent substrate 252, and is patterned and formed with a gate electrode 254 and a low electrode 256 of storage capacitor by using first photolithography/etching processes with a binary mask.

Referring to FIG. 11, a gate insulating film 258, an intrinsic semiconductor 262′, an extrinsic semiconductor layer 264′ and a second metallic layer 266′ are formed on the transparent substrate 252 in sequence.

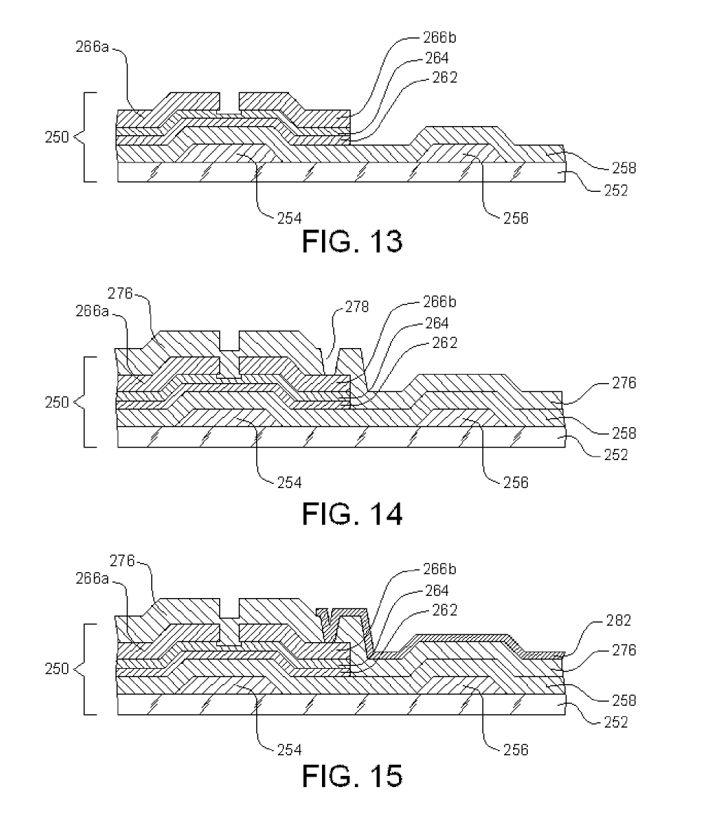

Referring to FIGS. 12 and 13, the intrinsic semiconductor 262′, the extrinsic semiconductor layer 264′ and the second metallic layer 266′ and formed to an intrinsic semiconductor 262, an ohmic contact layer (n⁺ a-Si) 264, a source electrodes 266a and a drain electrodes 266b by using second photolithography/etching processes and the gray tone mask 100 of the present invention, wherein a thin film transistors 250 is constituted by the gate electrode 254, the intrinsic semiconductor 262, the ohmic contact layer 264, the source electrodes 266a and the drain electrodes 266b.

More detailed, during second photolithography/etching processes a photo-resist 268 is formed on the second metallic layer 266′ and then irradiated by a proper light 270, e.g. an ultraviolet. The light 270, which is from the outside of the gray tone mask 100, irradiates the photo-resist 268 for exposing the photo-resist 268. After the light 270 irradiates the photo-resist 268, the photo-resist 268 (e.g. a positive type photo-resist) is decomposed so as to be dissolved in a developer. After being developed, baked and cured, the photo-resist 268 is patterned and formed with zero thickness, original thickness and intermediate thickness corresponding to the transparent region 112, the opaque region 114 and the gray tone region 116 of the gray tone mask 100, wherein the intermediate thickness is between the zero thickness and the original thickness. The intermediate thickness and the zero thickness of the photo-resist 268 define a channel region 272 and a contact region 274 respectively. During the etching process the second metallic layer 266′, the extrinsic semiconductor layer 264′ and the intrinsic semiconductor 262′ located over the contact region 274 are etched and removed. Since the photo-resist 268 located over the channel region 272 still has the intermediate thickness, the intermediate thickness of the photo-resist 268 can prevent the second metallic layer 266′ located thereunder from etching, shown in FIG. 12. Sequentially, the photo-resist 268 located over the channel region 272 is penetrated (etched) by using a plasma chemistry manner, and then the second metallic layer 266′ and a part of extrinsic semiconductor layer 264′ are etched so as to form the source electrodes 266a and the drain electrodes 266b, shown in FIG. 13. In other words, the method for forming the source electrodes 266a and the drain electrodes 266b is a method for patterning a work-piece, wherein all intrinsic semiconductor 262′, extrinsic semiconductor layer 264′ and second metallic layer 266′ can act as the work-pieces.

Referring to FIG. 14, a passivation layer 276 is deposited on the gate insulating film 258 and covers the thin film transistors 250. The passivation layer 276 is patterned and formed with a contact hole 278 by using third photolithography/etching processes and a binary mask.

Referring to FIG. 15, a transparent conducting layer (e.g. a transparent metallic layer made of indium tin oxide, ITO) is formed on the passivation layer 276, and patterned and formed to a pixel electrode 282 by using fourth photolithography/etching processes and a binary mask, wherein the pixel electrode 282 is electrically connected to the thin film transistor 250 via the contact hole 278.

Generally, the conventional method for manufacturing the liquid crystal display device includes five photolithography/etching processes and photo masks. However, the gray tone mask of the present invention can replace the binary mask so as to decrease the number of exposure steps and simplify photolithography processes. Thus, the method for manufacturing the liquid crystal display device by using the gray tone mask of the present invention only includes four photolithography/etching processes and photo masks.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A gray tone mask comprising:
a transparent substrate; and
a light blocking layer disposed on the transparent substrate and having a transparent region with a minimum thickness, an opaque region with a maximum thickness and a gray tone region with an intermediate thickness, wherein the intermediate thickness is between the minimum thickness and the maximum thickness, and the optical transmissivity of the gray tone region is approximately between 5% and 95%.

2. The gray tone mask as claimed in claim 1, wherein the light blocking layer is made of a metallic material.

3. The gray tone mask as claimed in claim 2, wherein the metallic material is selected from one of the group consisting of chromium, aluminum, tungsten, molybdenum, nickel, tantalum and their compounds.

4. The gray tone mask as claimed in claim 1, wherein the light blocking layer is made of a nonmetallic material.

5. The gray tone mask as claimed in claim 4, wherein the nonmetallic material is silicon or its compound.

6. The gray tone mask as claimed in claim 1, wherein the optical transmissivity of the transparent region is 100% when the value of the minimum thickness is zero.

7. The gray tone mask as claimed in claim 1, wherein the optical transmissivity of the opaque region is 0% when the value of the maximum thickness is more than a predetermined value.

8. The gray tone mask as claimed in claim 7, wherein the light blocking layer is made of chromium, and the optical transmissivity of the opaque region is 0% when the value of the maximum thickness is more than 1000 angstroms (A).

9. The gray tone mask as claimed in claim 1, wherein the light blocking layer is made of chromium, and the optical transmissivity of the gray tone region is 5% when the value of the intermediate thickness is 490 angstroms (A).

10. The gray tone mask as claimed in claim 1, wherein the light blocking layer is made of chromium, and the optical transmissivity of the gray tone region is 95% when the value of the intermediate thickness is 190 angstroms (A).

11. The gray tone mask as claimed in claim 1, wherein the gray tone region has a plurality of levels of the optical transmissivity.

12. The gray tone mask as claimed in claim 1, wherein the intermediate thickness includes a plurality of levels of thickness.

13. A method for manufacturing a gray tone mask comprising the following steps of:
providing a transparent substrate;
forming a light blocking layer on the transparent substrate, wherein the light blocking layer has a maximum thickness; and
patterning a part of the light blocking layer to have a minimum thickness and an intermediate thickness simultaneously by using photolithography/etching processes and a laser assisted process, wherein the minimum thickness, the maximum thickness and the intermediate thickness define a transparent region, an opaque region and a gray tone region respectively, the intermediate thickness is between the minimum thickness and the maximum thickness, and the optical transmissivity of the gray tone region is approximately between 5% and 95%.

14. The method as claimed in claim 13, wherein the light blocking layer is made of a metallic material.

15. The method as claimed in claim 14, wherein the metallic material is selected from one of the group consisting of chromium, aluminum, tungsten, molybdenum, nickel, tantalum and their compounds.

16. The method as claimed in claim 13, wherein the light blocking layer is made of a nonmetallic material.

17. The method as claimed in claim 16, wherein the nonmetallic material is silicon or its compound.

18. A method for patterning a work-piece comprising the following steps of:
providing a work-piece;
forming a photoresist on the work-piece;
exposing the photoresist with light by using a gray tone mask comprising a transparent substrate and a light blocking layer, wherein the light blocking layer is disposed on the transparent substrate and has a transparent region with a minimum thickness, an opaque region with a maximum thickness and a gray tone region with an intermediate thickness, the intermediate thickness is between the minimum thickness and the maximum thickness, and the optical transmissivity of the gray tone region is approximately between 5% and 95%;
developing the exposed photoresist so as to pattern the photoresist;
etching the work-piece so as to pattern the work-piece by using the patterned photoresist; and
removing the patterned photoresist.

19. The method as claimed in claim 18, wherein the work-piece is a thin film.

20. The method as claimed in claim 19, wherein the thin film is disposed on a thin film transistor substrate.
